(19) United States
(12) Patent Application Publication
(10) Pub. No.: US 2024/0413242 A1
(43) Pub. Date: Dec. 12, 2024

(54) LASER ANNEAL FORMED NANOSHEET LDMOS TRANSISTOR

(71) Applicant: Texas Instruments Incorporated, Dallas, TX (US)

(72) Inventors: Henry Litzmann Edwards, Garland, TX (US); Brian Goodlin, Plano, TX (US); Sujatha Sampath, Salt Lake City, UT (US)

(21) Appl. No.: 18/429,228

(22) Filed: Jan. 31, 2024

Related U.S. Application Data
(60) Provisional application No. 63/507,277, filed on Jun. 9, 2023.

(51) Int. Cl. H01L 29/78; H01L 29/06; H01L 29/16; H01L 29/423; H01L 29/66; H01L 29/775; H01L 29/786

(52) U.S. Cl. CPC H01L 29/7816; H01L 29/0673; H01L 29/1608; H01L 29/42392; H01L 29/66068; H01L 29/66969; H01L 29/775; H01L 29/78696

(57) ABSTRACT

A microelectronic device, e.g. an integrated circuit, includes first and second doped semiconductor regions over a semiconductor substrate. A semiconductor nanosheet layer is connected between the first and second semiconductor regions and has a bandgap greater than 1.5 eV. In some examples such a device is implemented as an LDMOS transistor. A method of forming the device includes forming a trench in a semiconductor substrate having a first conductivity type. A semiconductor nanosheet stack is formed within the trench, the stack including a semiconductor nanosheet layer and a sacrificial layer. Source and drain regions having an opposite second conductivity type are formed extending into the semiconductor nanosheet stack. The sacrificial layer between the source region and the drain region is removed, and the semiconductor nanosheet layer is annealed. A gate dielectric layer is formed on the semiconductor nanosheet layer, and a gate conductor is formed on the gate dielectric layer.

### CROSS-REFERENCE TO RELATED APPLICATIONS

This application claims the benefit of priority under 35 U.S.C. § 119 (e) of U.S. Provisional Application No. 63/507,277, filed Jun. 9, 2023, which is hereby incorporated by reference in its entirety.

### TECHNICAL FIELD

This disclosure relates to the field of microelectronic devices. More particularly, but not exclusively, this disclosure relates to gated devices including nanosheet semiconductor layers.

### BACKGROUND

Semiconductor components are being continually improved to reliably operate with smaller feature sizes. Fabricating semiconductor devices that have increasingly higher performance while meeting performance and reliability specifications presents diverse challenges.

### SUMMARY

This summary is provided to introduce a brief overview of disclosed concepts in a simplified form that are further described below in the detailed description including the drawings provided. This summary is not intended to limit the scope of the disclosure or the claims.

Disclosed examples include microelectronic devices, e.g. Integrated circuits. One example includes a microelectronic device including first and second doped semiconductor regions over a semiconductor substrate. A semiconductor nanosheet layer is connected between the first and second semiconductor regions and has a bandgap greater than 1.5 eV. In some examples the microelectronic device is implemented as a laterally diffused metal oxide semiconductor (LDMOS) transistor, in some examples the microelectronic device is implemented as a resistor, and in some examples the microelectronic device is implemented as a capacitor.

Other examples provide methods of forming an integrated circuit. In such examples a trench is formed in a semiconductor substrate having a first conductivity type. A semiconductor nanosheet stack is formed within the trench, the stack including a semiconductor nanosheet layer and a sacrificial layer. Source and drain regions having an opposite second conductivity type are formed extending into the semiconductor nanosheet stack. The sacrificial layer between the source region and the drain region is removed, and the semiconductor nanosheet layer is annealed. A gate dielectric layer is formed on the semiconductor nanosheet layer, and a gate conductor is formed on the gate dielectric layer.

### BRIEF DESCRIPTION OF THE VIEWS OF THE DRAWINGS

FIG. 1AA through FIG. 1BI are cross sections of an example microelectronic device including a laser anneal formed nanosheet LDMOS transistor in various stages of formation.

FIG. 2A and FIG. 2B are a cross sections of an example microelectronic device including a laser anneal formed nanosheet NMOS transistor after formation.

FIG. 3A and FIG. 3B are a cross sections of an example microelectronic device including a laser anneal formed nanosheet PMOS transistor after formation.

FIG. 4 is a graph of Rsp vs. BVDSS comparing the effect of an increasing number of nanosheets in a laser anneal formed nanosheet LDMOS transistor to the Rsp vs. BVDSS of a traditional LDMOS transistor.

FIG. 5 is a cross section of an example microelectronic device including a laser anneal formed nanosheet resistor after formation.

FIG. 6 is a cross section of an example microelectronic device including a laser anneal formed nanosheet MOSCAP after formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events unless otherwise stated. Furthermore, some of the illustrated acts or events may be omitted in some examples in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

The following co pending patent application has related subject matter and is hereby incorporated by reference: U.S. application Ser. No. 18/525,638, filed Nov. 30, 2023 (Attorney Docket No. T102552US02).

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values. Microelectronic devices are being continually improved to reliably operate with higher performance and smaller feature sizes.

Fabricating such microelectronic devices satisfying area scaling and reliability specifications presents ongoing challenges. Some gate-controlled devices such as metal-oxide-semiconductor (MOS) transistors include features for supporting high voltage operations, e.g. With a voltage applied to their drain (or drain structure) of 20 V, 30 V, 40 V, or even greater. MOS transistors may include drain diffusion profiles (or drain junction profiles) devised to support the high voltages applied to the drain, e.g. Having an extended portion to distribute the voltage drop across greater distances. Accordingly, such MOS transistors may be referred to as extended drain (ED) MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which may be referred to as complimentary drain-extended MOS or DECMOS transistors). Other gate controlled microelectronic devices may include a gated bipolar semiconductor device, a gated unipolar semiconductor device, an insulated gate bipolar transistor (IGBT), a MOS-triggered SCR, a MOS-controlled thyristor, and a gated diode ED transistors are scaled down to smaller sizes to reduce microchip cost and improve circuit performance by reducing parasitic resistance and capacitance, it can be challenging to maintain good reliability and yield, so it may be advantageous to improve transistor performance independently of lateral lithographic scaling.

Stacking transistor channels in three dimensions may be advantageous by reducing on-resistance and increasing on-current proportionally to the number of layers stacked. An example ED transistor as described in FIB. 1A-1AI may have a nanosheet layer doping profile whose dose lies in the resurf range 10¹²-10¹⁴ cm⁻², which sets the drain drift region contribution to source-drain on resistance (RDSON), which often is the dominant contribution. Therefore, stacking multiple nanosheet ED transistors in parallel in three dimensions provides the reduction of RDSON in a given area, so that the cost figure of merit specific on resistance (RSP) which is equal to the RDSON times the transistor area is reduced and power technology scaling can be improved for a given lithographic scaling capability. The physical geometry of the nanosheets for ED transistor differ from those in nanosheet digital CMOS transistors. In general, nanosheet digital CMOS transistors use nanosheet architecture including nanosheet layers just a few nanometers thick. For high voltage ED transistors, however, drain drift region mobility may be beneficial, and nanosheets thicker than 10 nm, with increasing thicknesses from 500 nm to 5 μm or greater, may be used to achieve target RSP values for efficient power circuit design. In some examples, the nanosheet thickness could be 750 nm to 5 μm, or such as 1 μm to 2 μm, which may keep the drain drift region doping concentration low enough to preserve high electron mobility, hence low RSP.

The disclosure includes several examples of microelectronic devices including a laser anneal formed nanosheet LDMOS transistor as well as several other laser anneal formed nanosheet microelectronic devices.

While such examples and variations may be expected to provide lower RDSON than some baseline devices of similar size and otherwise similar performance characteristics, no particular result is a requirement of the present disclosure unless explicitly recited in a particular claim. A semiconductor nanosheet stack, herein referred to as a “nanosheet stack” refers to a periodic structure of alternating layers of at least two different materials. A nanosheet stack may have many such layers, and in some cases may have as few as three layers including two layers of a first material with a layer of a second material between them. As used herein the term “nanosheet layer” refers to a layer of the first material, the first material being a semiconductor, within a nanosheet stack and having a thickness (in a direction normal to surface of the major surface of a substrate over which the nanosheet stack is formed) greater than 10 nm. As used herein, the term “sacrificial layer” means a layer of a second material within the nanosheet stack which while present in the as deposited nanosheet stack, is subsequently at least partially removed from the final laser anneal formed LDMOS transistor.

Wide bandgap materials may also be advantageously used to form a laser annealed nanosheet LDMOS transistor. Recrystallization and crystal grown of wide bandgap materials is possible by selecting the laser wavelength such that the laser energy is higher than the bandgap of the material to be recrystallized. When the laser energy is higher than the bandgap, electron-hole pares are generated with higher excited states in the conduction and valance band. The excess energy from the excited state is transformed as phonons/heat to the lattice, and as the wide bandgap material cools, annealing and recrystallization into highly ordered materials may be facilitated. By using a laser anneal process, wide bandgap semiconductors which may be difficult to deposit in single monocrystalline form may be deposited as amorphous or microcrystalline films and recrystallized using a laser anneal process to allow use in a nanosheet LDMOS transistor and other semiconductor devices. For the purposes of this disclosure, the wide bandgap semiconductor is a material including a group IV semiconductor material having a bandgap energy greater than silicon, a group III-V compound semiconductor having a bandgap energy greater than silicon, referred to herein as a III-V semiconductor material, or a group II-VI compound semiconductor having a bandgap energy greater than silicon, referred to herein as a II-VI semiconductor material, and other semiconductor materials having a bandgap energy greater than silicon, such as magnesium oxide and magnesium sulfide.

Bandgap energy generally refers to the energy difference (commonly expressed in electron volts) between a top of a valence band and a bottom of a conduction band in the semiconductor material. Bandgap energy is the energy required to promote a valence electron bound to an atom to become a conduction electron, which is free to move within the semiconductor material and serve as a charge carrier to conduct electric current. For the purposes of the disclosure wide bandgap semiconductors are those with a bandgap energy above 1.5 eV, while other semiconductors such as silicon and silicon-germanium are those with a bandgap of between 0.6 eV and 1.5 eV.

For the purposes of this disclosure, the term “group IV semiconductor material” includes silicon carbide and diamond, and alloy group IV semiconductor material, such as silicon carbide, or silicon-germanium-silicon carbide.

Similarly, the term “III-V semiconductor material” is understood to refer to semiconductor material in which group III elements, such as boron, aluminum, gallium, and indium, provide a portion of the atoms in the III-V semiconductor material, and group V elements, such as nitrogen, phosphorus, arsenic, and antimony, provide another portion of the atoms in the III-V semiconductor material. Some III-V semiconductor materials may include essentially one element from group III and one element from group V, such as gallium nitride, gallium phosphide, gallium arsenide, and aluminum nitride. Other III-V semiconductor materials, alloy III-V semiconductors, may include two or more elements from group III or two or more elements from group V, such as aluminum gallium nitride and indium aluminum gallium nitride.

Similarly, the term “II-VI semiconductor material” is understood to refer to semiconductor material in which group II elements, such as zinc and cadmium, provide a portion of the atoms in the II-VI semiconductor material, and group VI elements, e.g., Oxygen, sulfur, selenium, and tellurium, provide another portion of the atoms in the II-VI semiconductor material. Some II-VI semiconductor materials may include essentially only one element from group II and only one element from group VI, such as zinc sulfide, cadmium sulfide, zinc oxide, zinc selenide, and cadmium telluride. Other II-VI semiconductor materials, such as alloy II-VI semiconductor, may include two or more elements from group II and/or two or more elements from group VI, such as cadmium zinc telluride.

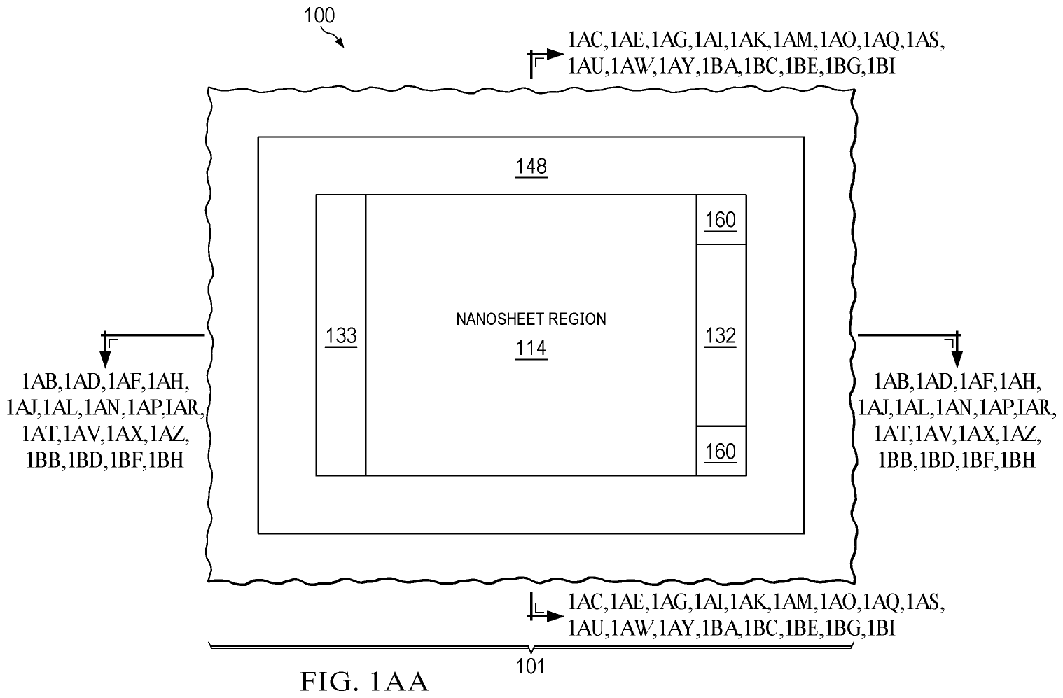

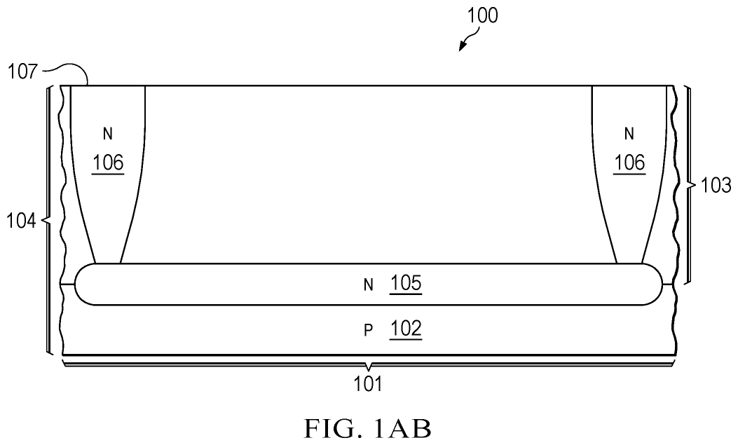

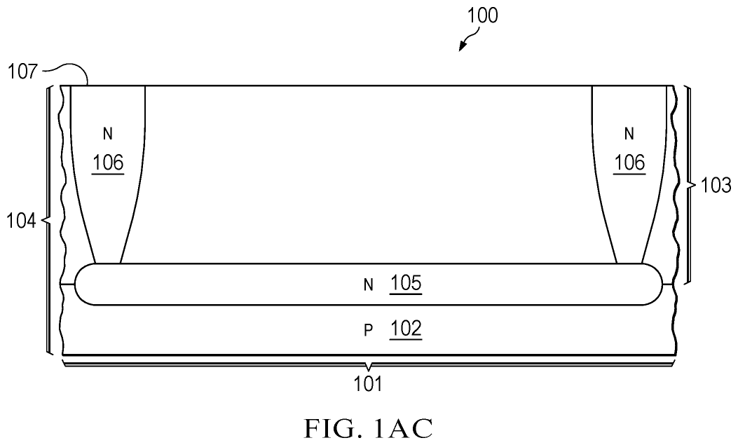

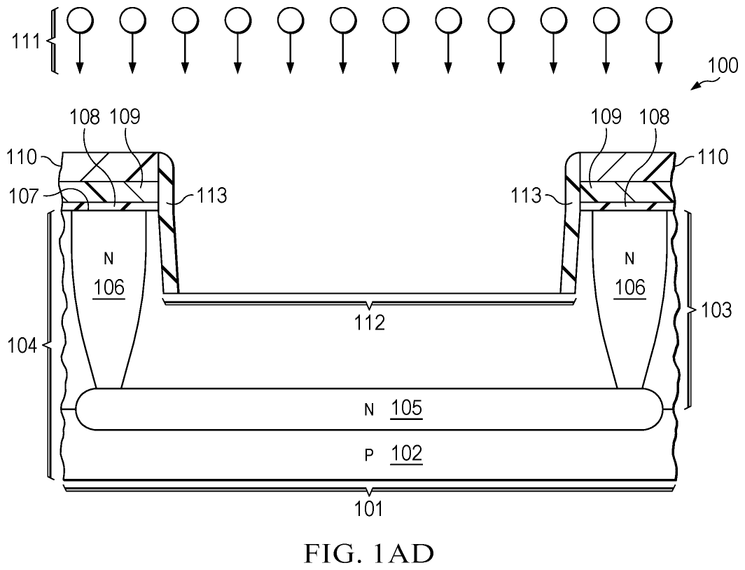

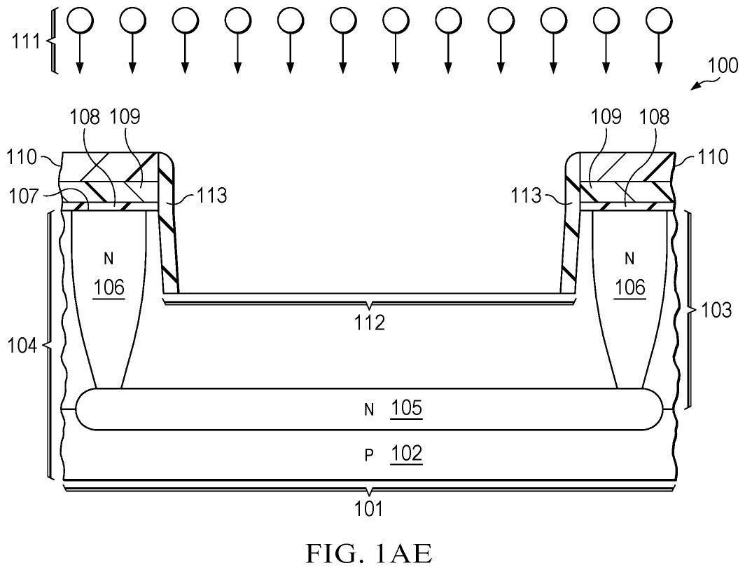

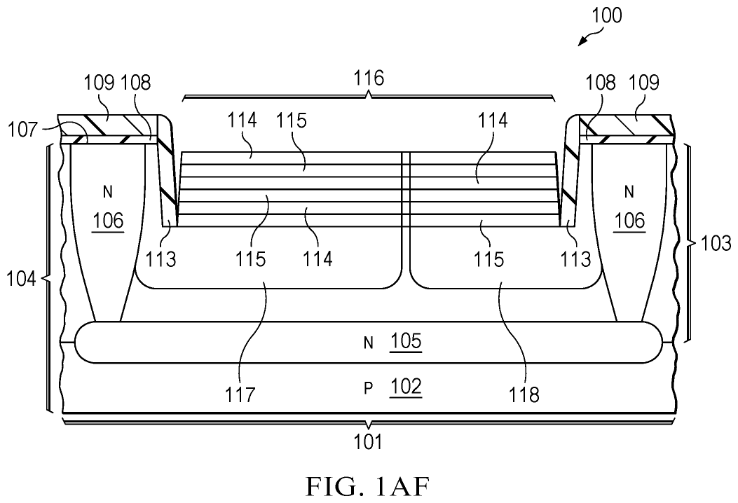

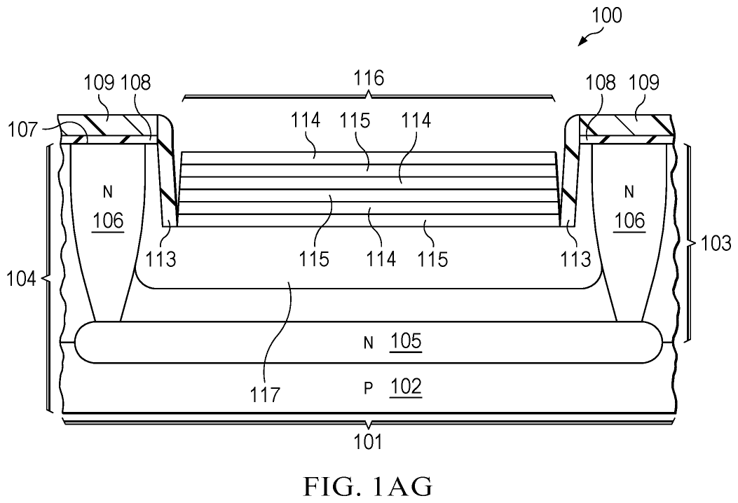

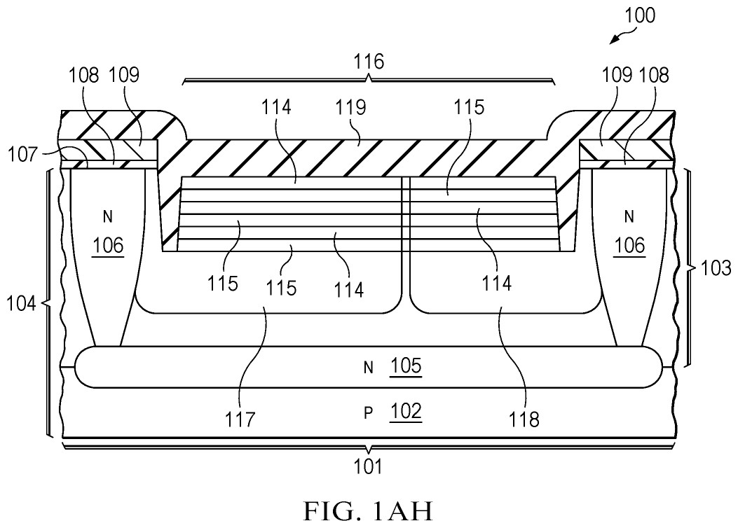

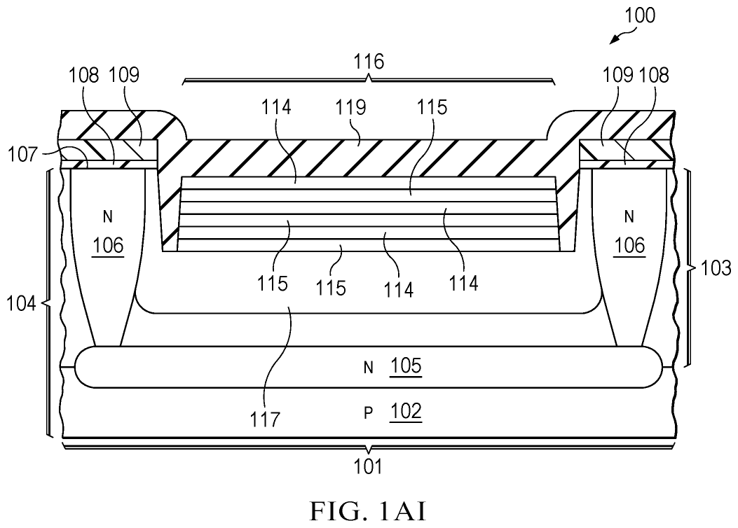

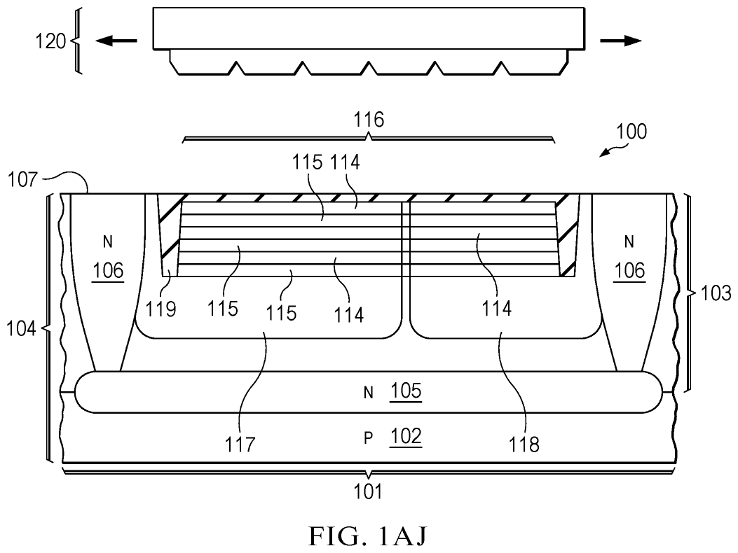

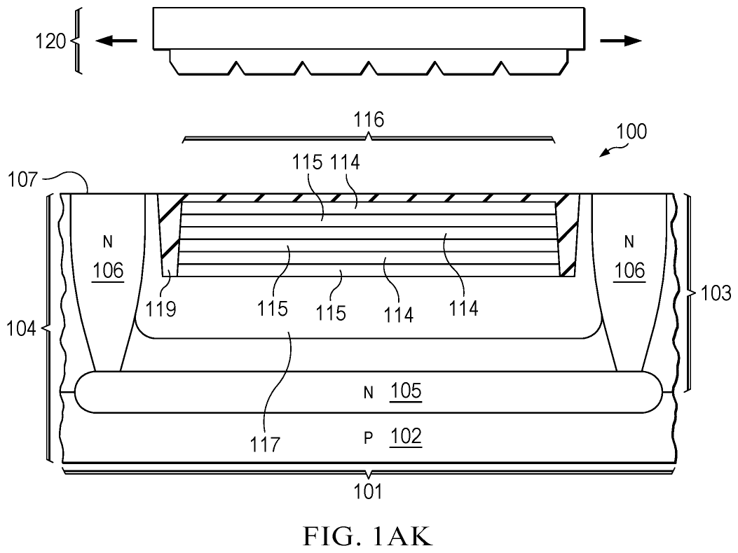

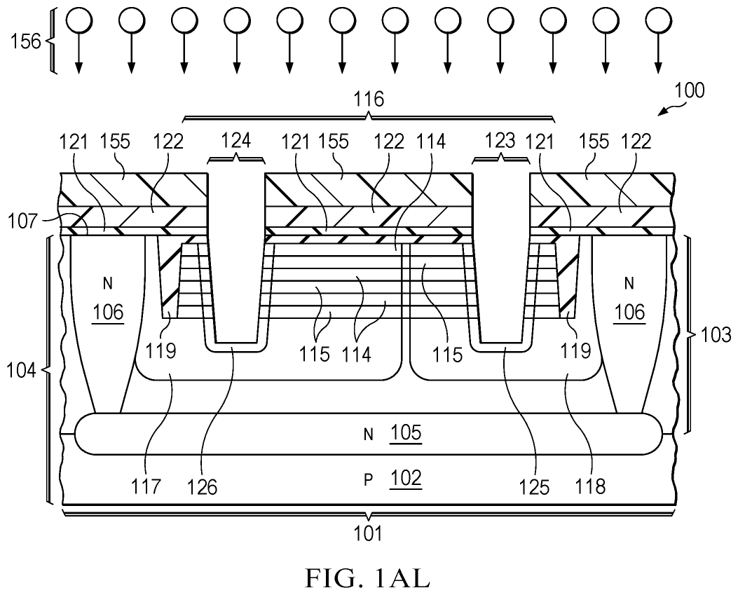

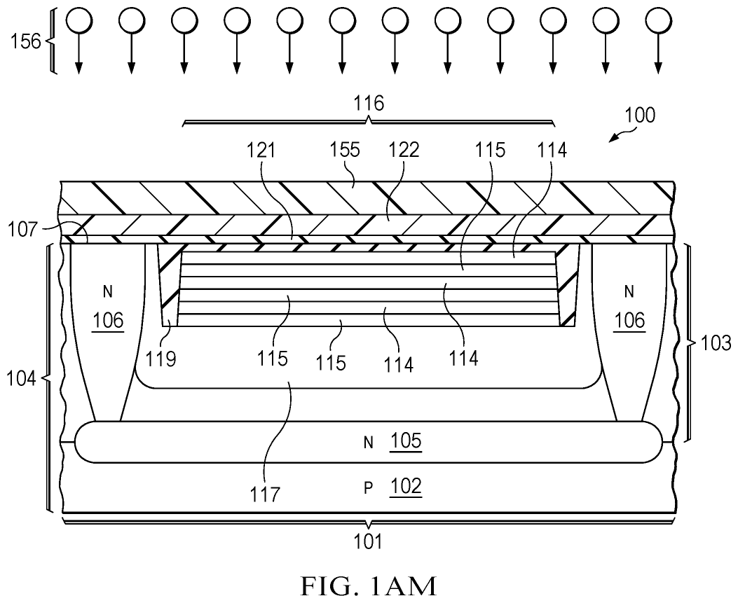

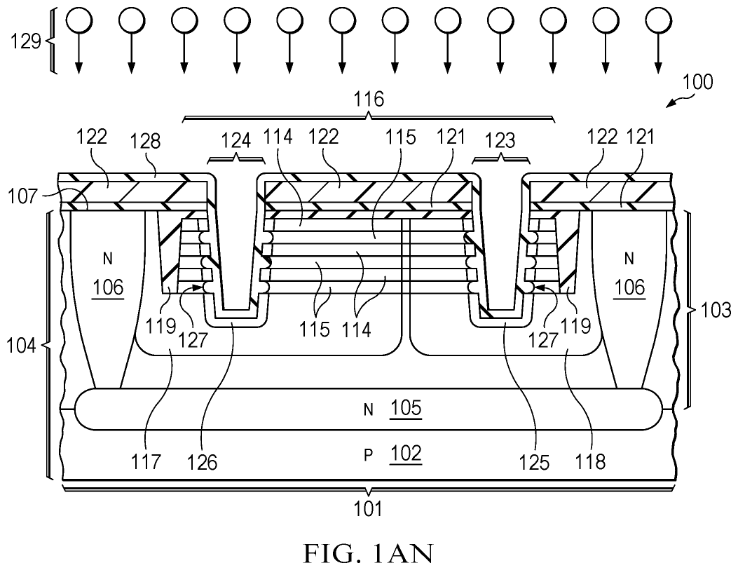

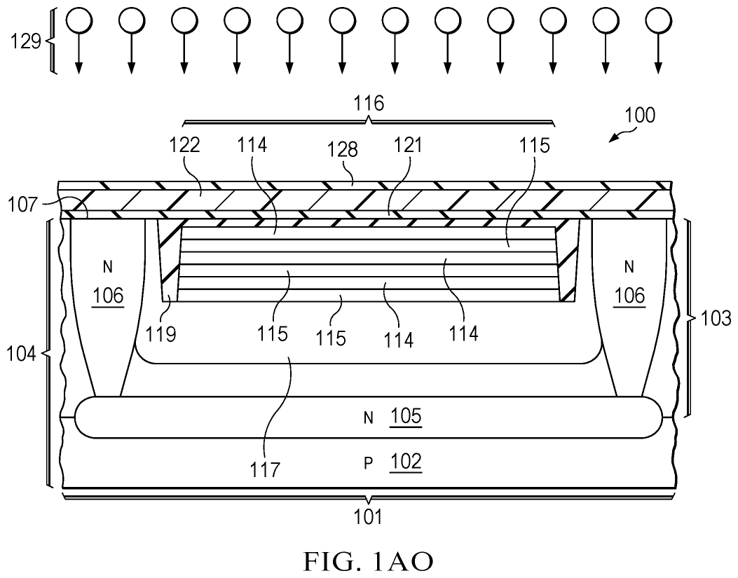

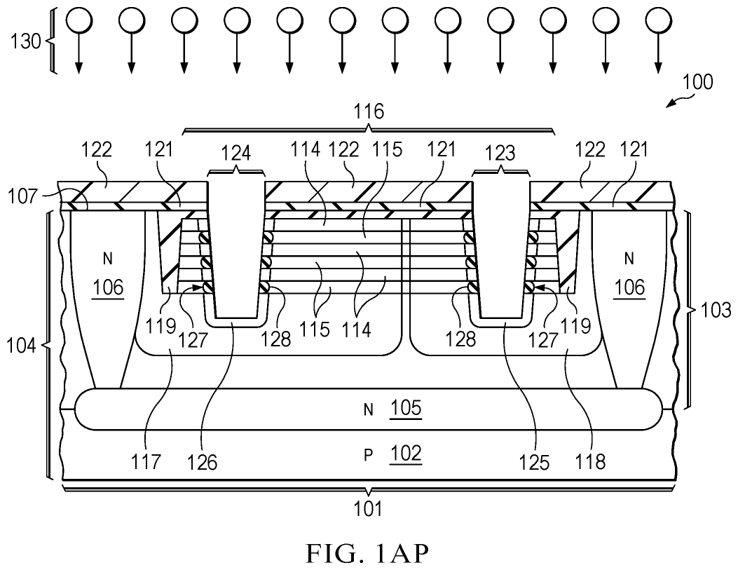

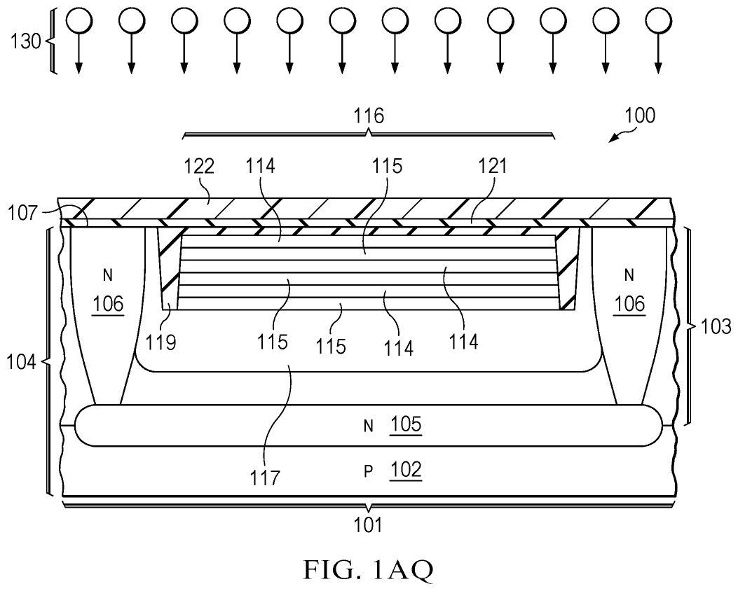

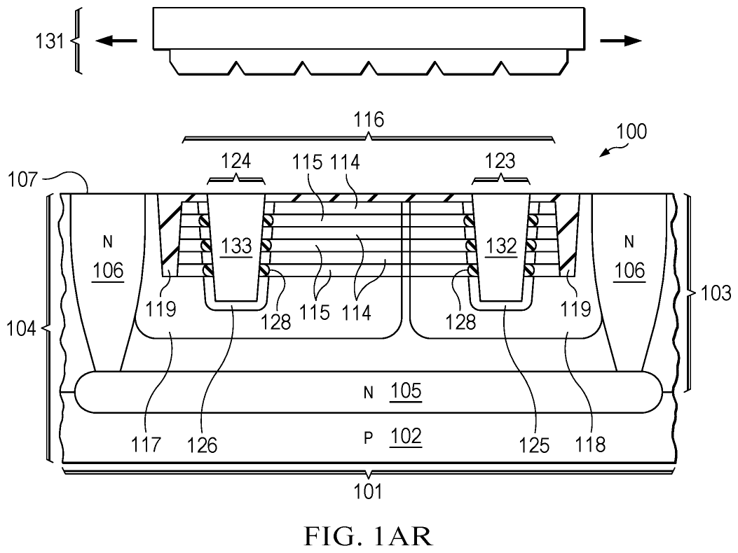

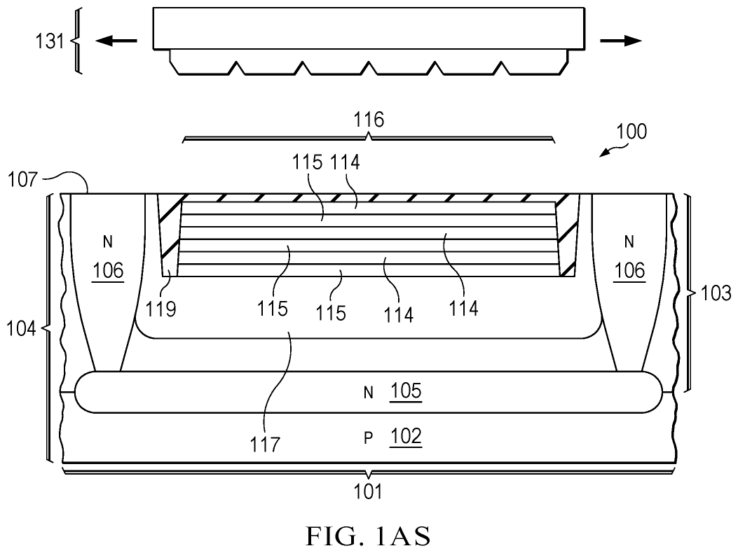

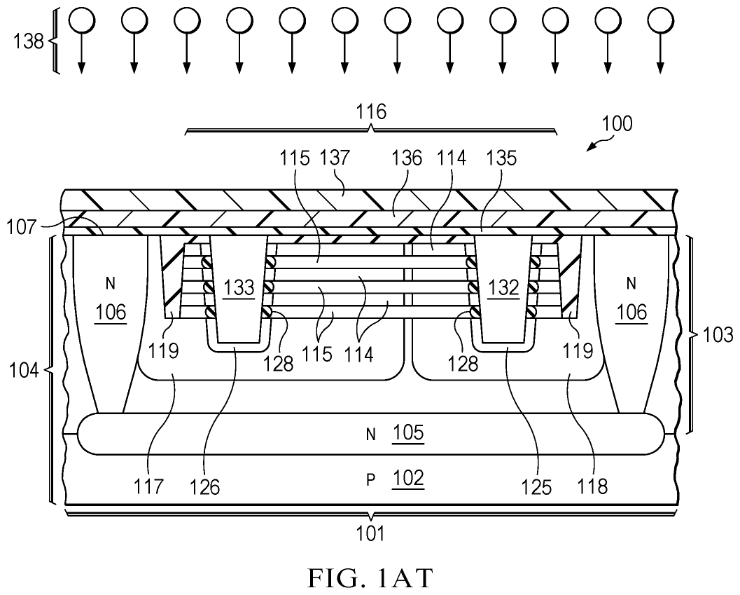

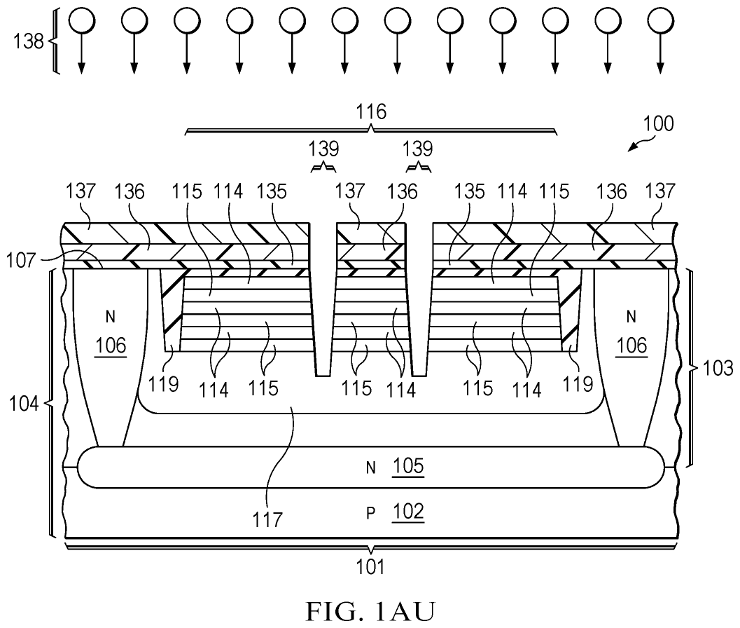

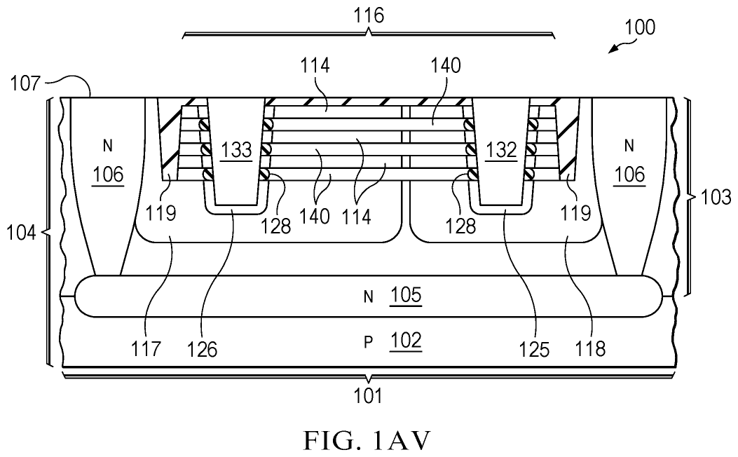

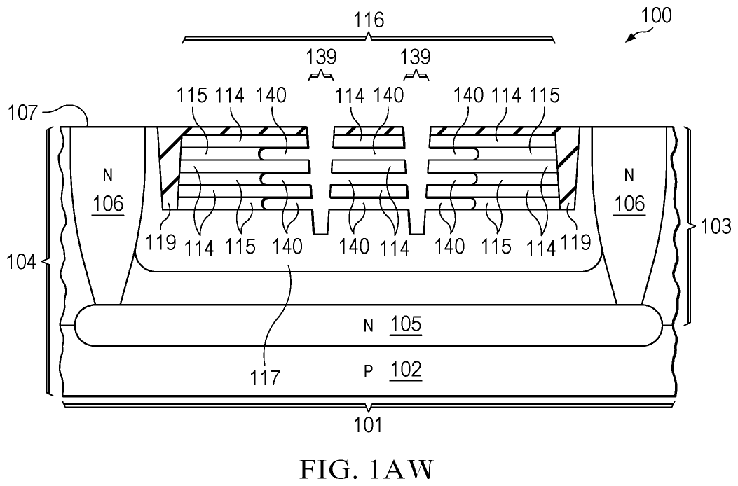

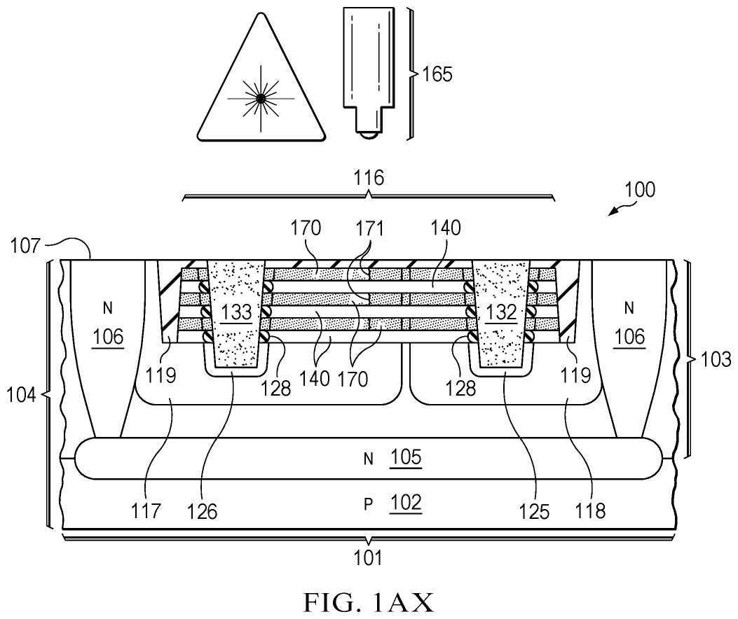

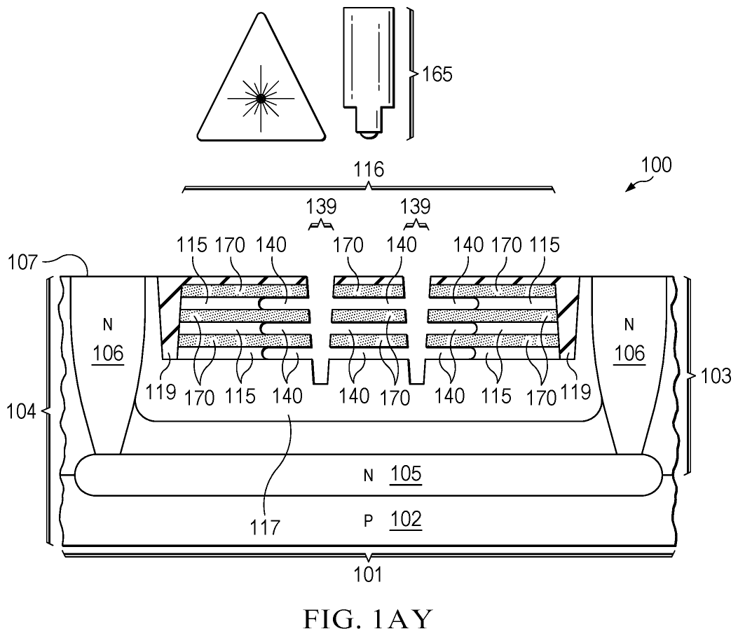

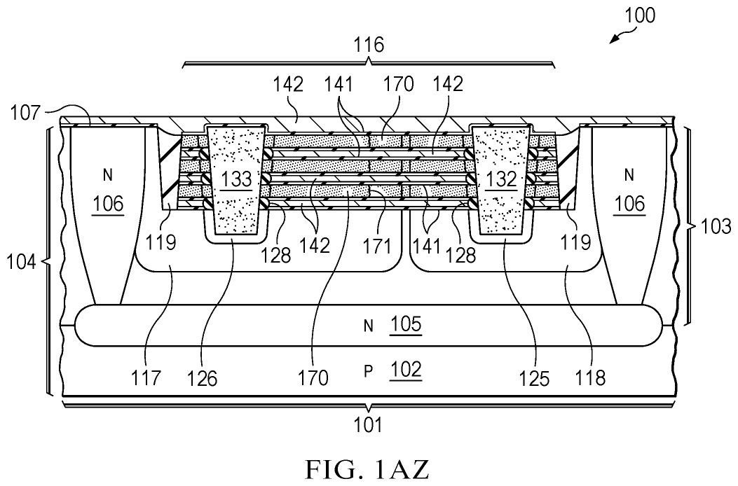

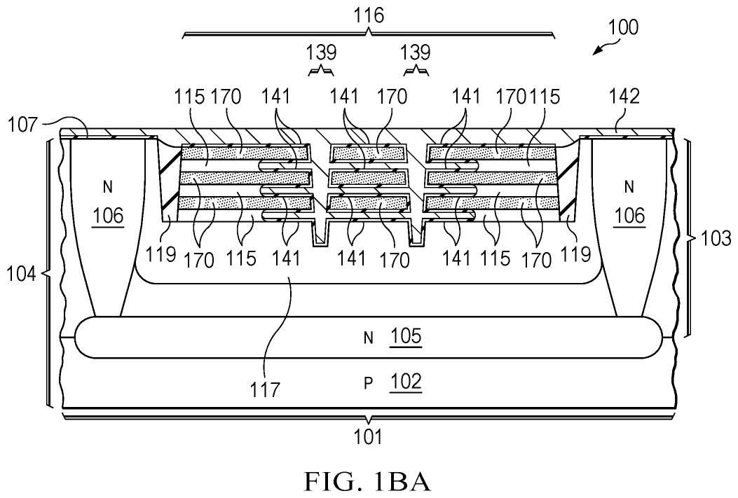

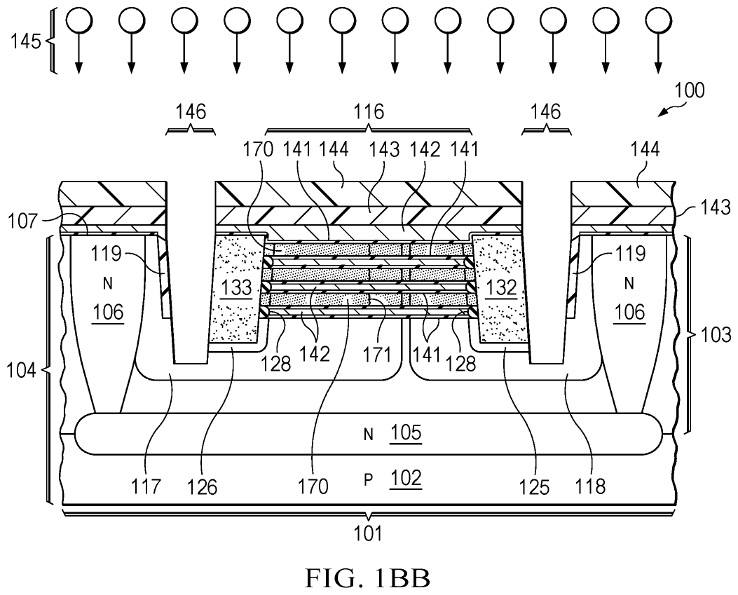

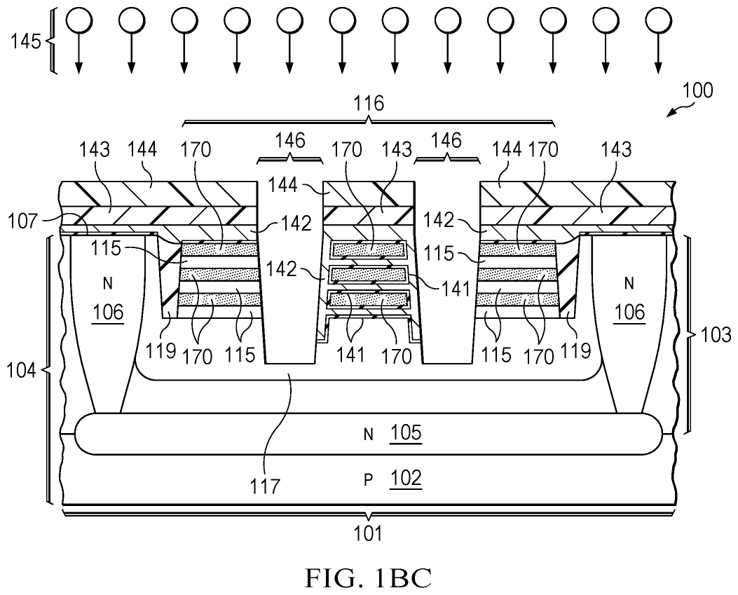

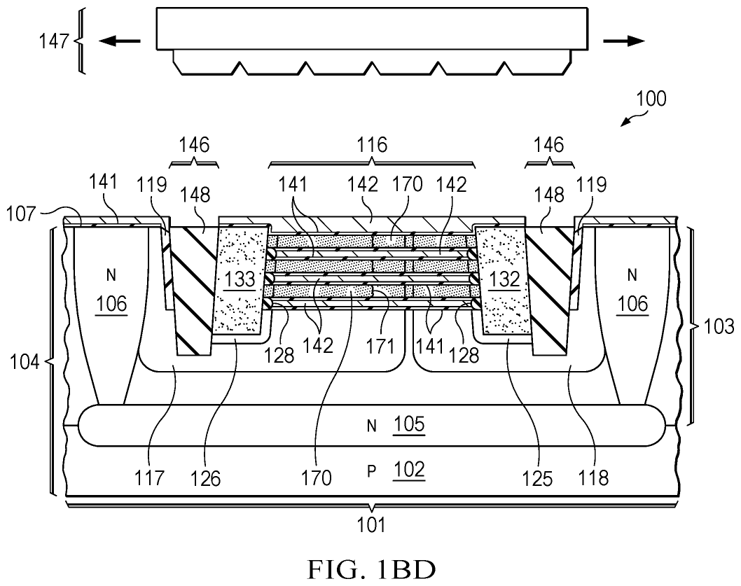

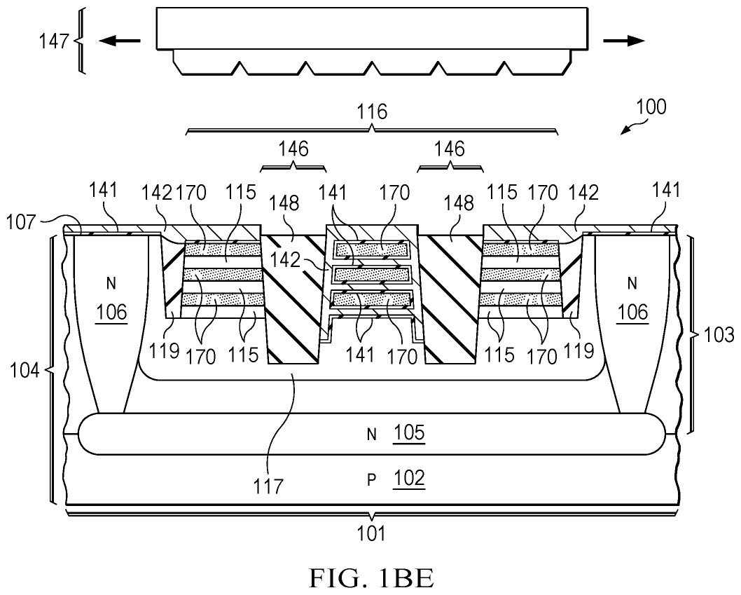

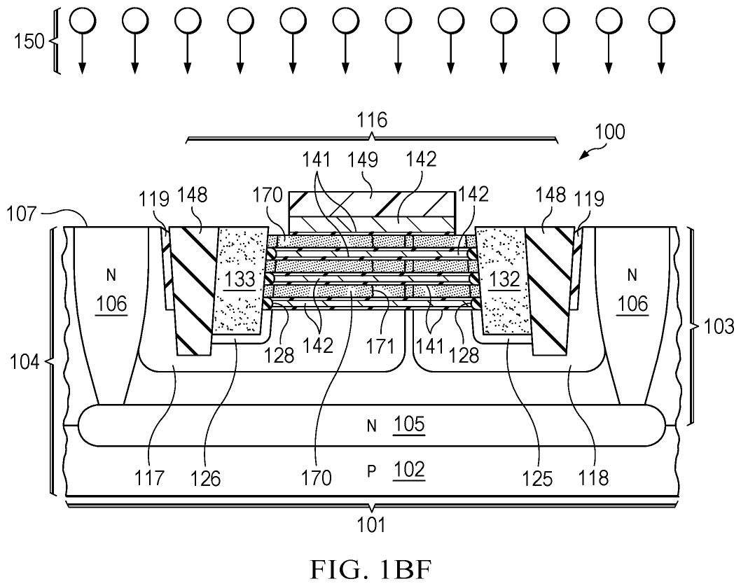

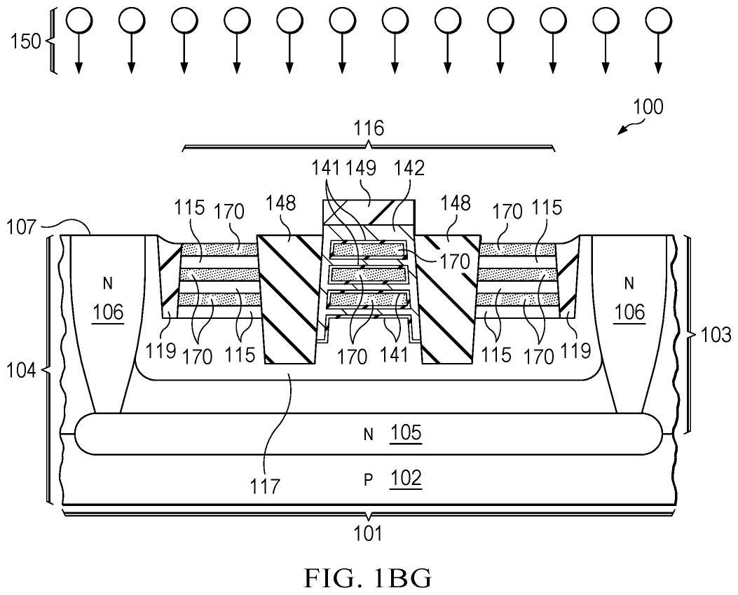

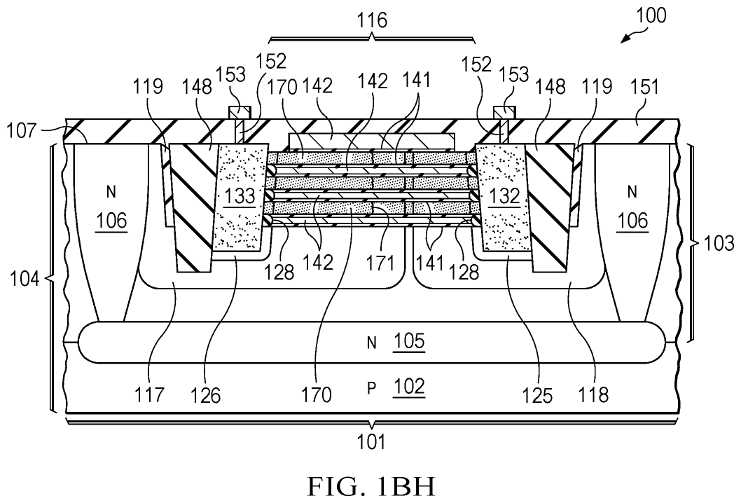

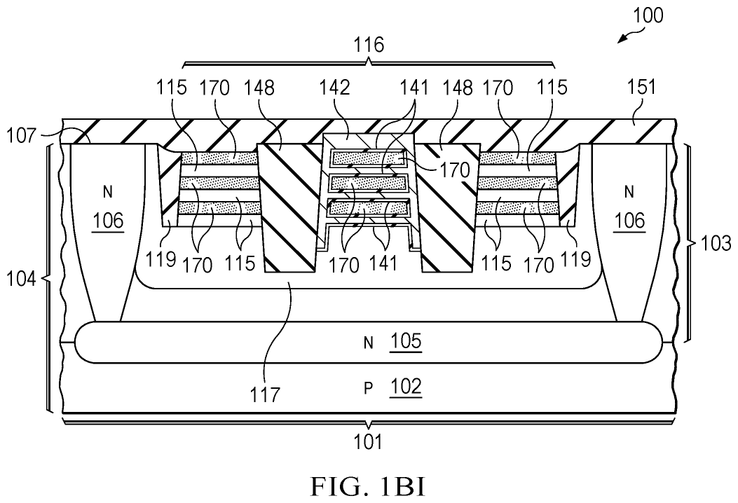

FIG. 1AA through FIG. 1BI are representative of a first type of microelectronic device 100 to which the principles of the disclosure may be beneficially applied. FIG. 1AB through 1BI show cross sections of an example microelectronic device 100, e.g. A laser anneal formed nanosheet LDMOS transistor 101, herein referred to as a nanosheet transistor 101, in successive stages of formation. The example nanosheet transistor 101 of FIG. 1AB through FIG. 1BI may be formed including nanosheet layers 114 of silicon carbide (a wide bandgap material). The nanosheet transistor 101 may also be formed including nanosheet layers 114 of any group IV semiconductor material, III-V semiconductor material, or II-VI semiconductor material, or some semiconducting oxides such as gallium oxide (Ga₂O₃). The nanosheet transistor 101 may also be formed including nanosheet layers 114 of a lower bandgap material such as silicon or silicon-germanium.

Without implied limitation, a nanosheet stack 116 in this example may include one or more nanosheet layers 114 described below that are implemented in an n-type laterally diffused metal oxide semiconductor (n-type LDMOS) nanosheet transistor 101. Another implementation of a p-type LDMOS transistor that includes the nanosheet stack 116 is a p-type LDMOS transistor that is within the scope of this example. In the example n-type nanosheet transistor 101, dopants of a first conductivity type are n-type dopants and dopants of a second conductivity type are p-type dopants. Additional implementations of the nanosheet layers 114 are not limited to, but may include in a wide bandgap nanosheet NMOS transistor 201, a wide bandgap nanosheet PMOS transistor 301, a nanosheet resistor 401, and a nanosheet MOSCAP 601. The example nanosheet transistor 101 is formed with nanosheet layers 114 of silicon carbide, and sacrificial layers 115 of silicon dioxide. Other combinations of materials may also be used, where the materials may be formed in the alternating layers, and one layer may be preferentially removed leaving intact semiconductor nanosheet layers.

FIG. 1AA shows a top-down representation of the microelectronic device 100 including nanosheet transistor 101 after formation. The top-down view shows a shallow trench isolation (STI) region 148 which is the outermost component of the nanosheet transistor 101. Nanosheet layers 114 are between a source region 132 and a drain region 133. A p-type back gate region 160 is conductively connected to the source region 132. For clarity, at successive stages of formation where figures are provided, a figure is provided showing a cross section along the axis through the source region 132, the nanosheet stack 116, and the drain region 133, with a companion cross section at the same successive stage of formation in a perpendicular manner across the nanosheet stack 116. While FIG. 1AA shows a single source region 132, a single drain region 133, and a single nanosheet stack 116, (cross section in FIG. 1AF) multiple source regions 132 and drain regions 133 may be added to increase the number of nanosheet channels. Increasing the number of nanosheet layers 114 may increase parallel conduction.

Referring to FIG. 1AB and FIG. 1AC, the microelectronic device 100 including a nanosheet transistor 101 is formed in and on a base wafer 102, such as a silicon wafer. The base wafer 102 may have a second conductivity type, which may be p-type in this example, as indicated in FIG. 1AB and FIG. 1AC. In an alternate version of this example, the base wafer 102 may include a dielectric material, such as silicon dioxide or sapphire, to provide a silicon-on-insulator substrate. A semiconductor material 103 is formed on the base wafer 102. The semiconductor material 103 includes primarily silicon, and may consist essentially of silicon and dopants, such as boron, and may have the second conductivity type, such as p-type. The semiconductor material 103 may be formed by an epitaxial process and may be 5 microns to 15 microns by way of example. The semiconductor material 103 extends to a top surface 107. The base wafer 102 and the semiconductor material 103 form the substrate 104.

A buried layer 105 may be formed in the substrate 104, extending into both the base wafer 102 and the semiconductor material 103. The buried layer 105 has a first conductivity type, opposite from the second conductivity type. In this example, the first conductivity type is n-type. The buried layer 105 may be formed by implanting dopants of the first conductivity type, such as phosphorus, arsenic, or antimony, into the base wafer 102 before the semiconductor material 103 is formed. The base wafer 102 may be annealed prior to forming the semiconductor material 103, and the semiconductor material 103 may subsequently be formed by an epitaxial process of thermal decomposition of silane, during which the dopants of the first conductivity type diffuse deeper into the base wafer 102 and into the semiconductor material 103, forming the buried layer 105.

A deep well 106 may be formed in the semiconductor material 103, extending from the top surface 107 of the substrate 104 to the buried layer 105. The deep well 106 may have the first conductivity type, n-type in this example. The deep well 106 may be formed by implanting dopants of the first conductivity type, such as phosphorus, into the semiconductor material 103, followed by a thermal drive to diffuse the implanted dopants to the buried layer 105 and activate the implanted dopants. The deep well 106 may have an average concentration of the dopants of the first conductivity type that is at least 2 times to 10 times greater than an average concentration of dopants of the second conductivity type in the semiconductor material 103 outside of the deep well 106. The deep well 106 provides isolation between the nanosheet transistor 101 and other components of the microelectronic device 100. The deep well 106 may preferably be degenerately doped to provide low leakage between the nanosheet transistor 101 and other components of the microelectronic device 100.

Referring to FIG. 1AD and FIG. 1AE, cross sections are shown after a nanosheet stack trench 112 has been formed. After formation of the buried layer 105 and the deep well 106, first pad oxide layer 108 may be formed on the top surface 107 of the substrate 104. The first pad oxide layer 108 may include primarily silicon dioxide, may be formed by a thermal oxidation process or a thermal chemical vapor deposition (CVD) process, and may have a thickness of 5 nanometers to 200 nanometers, by way of example. A first hard mask layer 109 may be formed on the first pad oxide layer 108. The first hard mask layer 109 may include a layer of a material composed primarily of silicon nitride, and a layer of a material containing primarily silicon dioxide. The first hard mask layer 109 may have a thickness of 50 nanometers to 3 microns, depending on a depth of the nanosheet stack trench 112. The first pad oxide layer 108 may provide stress relief between the semiconductor material 103 and the first hard mask layer 109. The silicon nitride portion of the first hard mask layer 109 may provide a stop layer for subsequent etch and planarization processes. The silicon dioxide layer of the first hard mask layer 109 may provide a hard mask during a nanosheet stack trench etch 111 to form the nanosheet stack trench 112. A nanosheet stack trench photomask 110 may be formed on the first hard mask layer 109 with openings which expose the first hard mask layer 109 in areas for the nanosheet stack trench 112.

A nanosheet stack trench etch 111 forms the nanosheet stack trench 112 in the substrate 104. The nanosheet stack trench etch 111 may include multiple steps. After the nanosheet stack trench etch 111, the nanosheet stack trench photomask 110 is removed. A nanosheet stack trench dielectric sidewall 113 is formed after the nanosheet stack trench photomask 110 is removed. The nanosheet stack trench dielectric sidewall 113 is formed by depositing a blanket layer of a dielectric such as silicon dioxide or silicon nitride followed by an anisotropic etch (neither process specifically shown). The anisotropic etch leaves a nanosheet stack trench dielectric sidewall 113 which prevents deposition of the nanosheet layers 114 or the sacrificial layers 115 during the nanosheet stack 116 formation process. After the formation of the nanosheet stack trench dielectric sidewall 113, the horizontal surface of the nanosheet stack trench 112 is free of dielectric material.

Referring to FIG. 1AF and FIG. 1AG, cross sections are shown after a nanosheet stack 116, a drain drift region 117 and the p-type well region 118 have been formed. Not explicitly shown in these views, the p-type well region connects to the p-type back gate region 160. The nanosheet stack 116 may be formed by any appropriate thin film deposition method to form alternating layers of the sacrificial layer 115 and the nanosheet layer 114. The morphology of the sacrificial layer 115 and the nanosheet layer 114 may be amorphous to polycrystalline. The nanosheet layers 114 may have a thickness in a range between about 10 nm and about 5 μm, though other thicknesses are contemplated. In the example device, the nanosheet layer 114 comprises silicon carbide and the sacrificial layer 115 comprises silicon dioxide. Other semiconductors may be used as the nanosheet layer 114, and other dielectric materials, e.g. SiN, and other semiconductor materials that can be selectively removed with respect to the nanosheet layer 114, e.g. SiGe, may be used as the sacrificial layer 115. The choice of nanosheet layer 114 and sacrificial layer 115 may be chosen such that the sacrificial layer 115 may be removed by a plasma etch or wet etch process while the nanosheet layer 114 remains intact.

The drain drift region 117 is formed in the substrate 104, in the semiconductor material 103, a portion of the nanosheet stack 116, and will subsequently surround the drain region 133 referred to in FIG. 1AR. One or more n-type implants are performed to form the drain drift region 117 (which may be referred to as an n-drift region) in the substrate 104. The n-type dopant that defines the n-drift region 117 may be implanted in one step or in multiple steps. Arsenic may also be implanted with a similar dose with an energy relatively higher than the phosphorus implant. The n-drift region 117 has an average doping concentration less than the average doping concentration of the drain region 133.

A p-type well region 118 is formed in the substrate 104 in the semiconductor material 103 and a portion of the nanosheet stack 116, and will subsequently surround the source region 132 referred to in FIG. 1AR. One or more p-type implants are performed to form the p-type well region 118 (which may be referred to as an p-well region) in the substrate 104. The p-type dopant that defines the p-type well region 118 may be implanted in one step or in multiple steps. The p-type well region 118 may also receive a heavier implanted dose which does not deplete under reverse bias and is heavy enough to suppress source/drain leakage in the off state. In some examples, the p-type well region 118 doping may be too heavy for use in a p-type wide bandgap nanosheet LDMOS transistor. In such examples, a p-type drift implant may be beneficial.

Referring to FIG. 1AH and FIG. 1AI, cross sections are shown after a dielectric layer 119 is deposited. The dielectric layer 119 forms a dielectric gap fill between the nanosheet stack 116 and the substrate 104.

Referring to FIG. 1AJ and FIG. 1AK, cross sections are shown after a chemical mechanical polish (CMP) process 120 has removed the dielectric layer 119 outside the nanosheet stack trenches 112. The dielectric layer 119 acts as a gap fill between the nanosheet stack 116 and the substrate 104. After the CMP process 120, the first hard mask layer 109 is removed.

Referring to FIG. 1AL and FIG. 1AM, cross sections are shown after a source/drain trench etch 156 forms a source trench 123 and a drain trench 124. A second pad oxide layer 121 and a second hard mask layer 122 are first formed followed by a source/drain photolithographic pattern 155. After the formation of the source/drain photolithographic pattern 155, a multi-step etch process is used to etch the second hard mask layer 122, the second pad oxide layer 121, and the nanosheet stack 116 in the open areas of the source/drain photolithographic pattern 155. After the source trench 123 and the drain trench 124 are formed, a p-body photolithographic pattern is formed (not specifically shown) and an angled implant (not specifically shown) is used to implant p-type dopants in the region surrounding the source trench 123 to form a p-type body region 125. After the p-type body region 125 is formed, the p-body photolithographic pattern is removed and a n-buffer photolithographic pattern is formed (not specifically shown) and an angled implant (not specifically shown) of a n-type dopant is used to implant n-type dopants in the region surrounding the drain trench 124 to form a n-type buffer region 126. After the formation of the n-type buffer region 126, the n-type buffer photolithographic pattern is removed. Alternatively, plasma doping may be used in some circumstances to implant dopants and form the p-type body region 125 and the n-type buffer region 126.

Referring to FIG. 1AN and FIG. 1AO, cross sections are shown after an inner spacer dielectric 128 has been deposited. After the formation of the p-type body region 125, and the n-type buffer region 126 are formed, an isotropic sacrificial layer recess etch (not specifically shown), either a plasma etch or a wet etch selective to the sacrificial layers 115 is used to remove a portion of the sacrificial layers 115, forming an inner spacer recess 127 near the sidewalls of the p-type body region 125 and the n-type buffer region 126. After the inner spacer recess 127 is formed, a conformal layer of an inner spacer dielectric 128 is formed. The inner spacer dielectric 128 is a conformal dielectric layer which fills the inner spacer recess 127. After formation, the inner spacer dielectric 128 remains intact during the removal of the sacrificial layer 115 referred to in FIGS. 1AV and 1AW, and the choice of inner spacer dielectric 128 may vary based on the choice of the sacrificial layer 115.

Referring to FIG. 1AP and FIG. 1AQ, cross sections are shown after an inner spacer dielectric etch 130 The inner spacer dielectric etch 130 is an anisotropic etch which removes the inner spacer dielectric 128 from the top surface of the second hard mask layer 122, and regions inside the source trench 123 and the drain trench 124, with inner spacer dielectric 128 remaining in those regions where the sacrificial layer recess etch recessed the sidewalls of the source trench 123 and the drain trench 124.

Referring to FIG. 1AR and FIG. 1AS cross sections are shown after a polysilicon trench CMP process 131 has completed the formation of a source region 132 and a drain region 133. After the formation of the inner spacer dielectric 128 discussed in FIG. 1AP and FIG. 1AQ, a n-type polysilicon deposition (not specifically shown) fills the source trench 123 and the drain trench 124 with n-type polysilicon. The n-type silicon deposition to fill the source trench 123 and the drain trench 124 may also be an epitaxial deposition. A polysilicon trench CMP process 131 is used to remove polysilicon outside of source trench 123 and the drain trench 124. After the polysilicon trench CMP process 131, the second hard mask layer 122 and the second pad oxide layer 121 are removed. After the polysilicon CMP process is complete, processes similar to those shown in FIG. 1AL through FIG. 1AS may be repeated using a p-type in-situ polysilicon deposition to form p-type regions such as the p-type back gate region 160 (out of the plane of FIG. 1AR and FIG. 1AS but referred to in FIG. 1AA). The p-type back gate region 160 is later conductively connected to the source region 132 either through contacts 152 and an interconnect 153, or through a common silicide connection (not specifically shown).

Referring to FIG. 1AT and FIG. 1AU cross sections are shown after a gate trench 139 is formed. After the formation of the source region 132 and drain region 133 referred to in FIG. 1R, a third pad oxide 135 and a third hard mask 136 are formed. A gate trench photolithographic mask 137 is patterned on the third hard mask 136. A multi-step gate trench etch 138 removes the third hard mask 136, the third pad oxide 135, and the nanosheet stack 116 in regions exposed by the gate trench photolithographic mask 137 forming the gate trench 139. After the formation of the gate trench 139, the gate trench photolithographic mask 137, the third hard mask 136, and the third pad oxide 135 are removed.

Referring to FIG. 1AV and FIG. 1AW cross sections are shown after a plasma etch or a wet etch which selectively removes the sacrificial layers 115 of the nanosheet stack 116 leaving sacrificial layer voids 140 between adjacent nanosheet layers 114 remaining. The sacrificial layer voids 140 leave the nanosheet layers 114 suspended over the substrate 104 by attachments to the source region 132 and the drain region 133. After removing the sacrificial layers 115 a cleanup process that includes supercritical CO₂ may be employed to remove residues.

Referring to FIG. 1AX and FIG. 1AY, cross sections are shown after a laser anneal process 165 crystallizes the nanosheet layers 114 referred to in FIG. 1AB through FIG. 1AW from an amorphous, microcrystalline, or polycrystalline form into crystalline nanosheet layers 170. The nanosheet layers 170 may be monocrystalline, or may include a number of crystalline domains low enough that associated defects or grain boundaries do not prevent the use of the nanosheet layers 170 as a functional element of the nanosheet transistor 101. The laser anneal process 165 allows crystal growth of the nanosheet layers 114 into crystalline nanosheet layers 170 by providing localized heating and subsequent annealing to the nanosheet layers 114. Additionally, the laser anneal process 165 may be beneficially applied in the formation of the crystalline nanosheet layers 170 as the laser anneal process 165 may provide effective heating to thin layers of material.

In the example nanosheet transistor 101, the nanosheet layers 114 are silicon carbide and may be amorphous, microcrystalline, or polycrystalline as-deposited. The optical absorption of polycrystalline SiC at UV wavelengths is high, allowing efficient local heating of the nanosheet layer 114. Multiple laser pulses with a short dwell time at one or more wavelengths may be used to heat and recrystallize the amorphous SiC in the nanosheet layer 114 into a crystalline lattice structure of the nanosheet layer 170. In the current example of the nanosheet transistor 101 having multiple nanosheets, the nanosheet layer 114 nearest the top surface 107 may form a crystalline nanosheet layer 170 which may become more transparent to the incoming UV laser pulse as it crystallizes, allowing UV laser radiation of subsequent laser pulses to pass through the crystalline nanosheet layer 170 nearest the top surface and crystallize the nanosheets layers 114 below the top surface 107 into crystalline nanosheet layers 170.

In one example for crystallization of silicon carbide using a laser anneal process 165, a UV excimer laser (source which includes a noble gas such as Ar, Kr or Xe) and a halogen such as F or Cl may be used. Such a laser may operate in a wavelength range of approximately 150-400 nm, in a pulsed mode, with a pulse time or dwell time on the order of nanoseconds per pulse, and an energy range of approximately 10 mJ to 1 J. A short wavelength UV laser is advantageous for the laser anneal process 165 as the short wavelength UV laser enables absorption which is substantially limited to a nanometer range of depth of the nanosheet stack 116.

As the crystalline nanosheet layers 170 are being formed, crystalline domains may grow from the source region 132 and the drain region 133 towards a point between the source region 132 and drain region 133. A grain boundary 171 may form at the interface between such crystalline domains. Additional laser pulses of the laser anneal process 165 may further anneal the crystalline domains to reduce any lattice mismatch at the grain boundary 171.

The laser power, dwell time, and pulse shape may be adjusted accordingly for SiC, Si, and other nanosheet layer 114 materials which are within the scope of the disclosure to account for differences in bandgap, melting temperature, recrystallization characteristics, and the thickness of the nanosheet layers 114 in the nanosheet stack 116.

Referring to FIG. 1AZ and FIG. 1BA, cross sections are shown after a nanosheet gate dielectric layer 141 and a gate conductor 142 are formed. The nanosheet gate dielectric layer 141, which may be formed by a deposition of the nanosheet gate dielectric layer 141, which forms a continuous sheath around each of the crystalline nanosheet layers 170 between the source region 132 and the drain region 133. The gate conductor 142 fills the sacrificial layer voids 140, the gate trench 139, and forms a continuous layer over the nanosheet stack 116.

Referring to FIG. 1BB and FIG. 1BC, cross sections are shown after an isolation trench etch 145 has formed an isolation trench 146. To form the isolation trench 146, a hard mask 143 is formed on the gate conductor 142. After formation of the hard mask 143, a photomask 144 is formed. The isolation trench etch 145 forms the isolation trench 146 in the open areas of the photomask 144 by etching portions of the hard mask 143, the gate conductor 142, the nanosheet gate dielectric layer 141, and the nanosheet stack 116. The isolation trench etch 145 also etches into, and stops in the semiconductor material 103. Specifically within the drain drift region 117 and the p-type well region 118. After the isolation trench etch 145, the photomask 144 is removed. The hard mask 143 remains in place as an etch stop for a subsequent STI CMP process 147 referred to in FIG. 1BD and FIG. 1BE. The isolation trench etch 145 may also be used to create an array of wide bandgap nanosheet transistors (not specifically shown) by etching a plurality of trenches within a larger nanosheet transistor 101 that isolate a plurality of sub-transistors similar to the nanosheet transistor 101, each sub-transistor containing a separate source region 132, drain region 133, and nanosheet stack 116.

Referring to FIG. 1BD and FIG. 1BE, cross sections are shown after the STI CMP process 147 has formed the STI region 148. The STI region 148 is formed by first forming a layer of a silicon dioxide or similar dielectric in the isolation trench 146 and on the hard mask 143 (referred to in FIG. 1BC) of the nanosheet transistor 101. A high-density plasma (HDP) deposition or a high aspect ratio plasma (HARP) technique may be used to fill the isolation trench 146 by way of example. A STI CMP process 147 may be used to remove the dielectric overburden outside the isolation trench 146, leaving an STI region 148 in the isolation trench 146. The STI region 148 isolates the crystalline nanosheet layers 170, the source region 132, and the drain region 133 from the remaining nanosheet stack 116 between the STI region 148 and the dielectric layer 119. After the STI CMP process 147, the hard mask 143 referred to in FIG. 1BB and FIG. 1BC (not specifically shown in FIG. 1BD and FIG. 1BE), is removed using a phosphoric acid chemistry, and a HF based chemistry is used to achieve the specified final profile of the STI region 148.

FIG. 1BF and FIG. 1BG, cross sections are shown after a gate conductor plasma etch 150. A gate conductor photomask 149 is formed on the gate conductor 142. After the formation of the gate conductor photomask 149, a gate conductor plasma etch 150 removes the gate conductor 142 is the open areas of the gate conductor photomask 149. After the gate conductor plasma etch 150, the gate conductor photomask 149 is removed.

After the gate conductor photomask 149 is removed, sidewall spacers (not specifically shown) may be formed on the vertical surfaces of the gate conductor 142 and may extend 50 nm to 200 nm from the lateral edge of the gate conductor 142. The sidewall spacers may prevent subsequent silicide formation on the vertical surfaces of the gate conductor 142 and on a portion of the crystalline nanosheet layers 170 or other layers which may form silicides under the sidewall spacers.

FIG. 1BH and FIG. 1BI, shows cross sections of the nanosheet transistor 101 after a first level of interconnects 153 is complete. A metal silicide layer (not specifically shown) may be formed on the source region 132, the drain region 133, the p-type back gate region 160 (out of the plane of the cross section, referred to in FIG. 1AA) and exposed portions of the gate conductor 142. The metal silicide layer may provide ohmic electrical connections to the source region 132, the drain region 133, the p-type back gate region 160 and the gate conductor 142 with lower resistances compared to a similar microelectronic device without metal silicide layer.

A pre-metal dielectric (PMD) layer 151 is formed over the top surface 107 of the substrate 104. The PMD layer 151 may include one or more dielectric layers, such as silicon nitride, silicon oxynitride, and silicon dioxide. In some examples, the PMD layer 151 includes a PMD liner (not specifically shown) and a main dielectric sublayer formed on the PMD liner. Subsequently, the PMD layer 151 may be planarized by a CMP process (not specifically shown). Contacts 152, e.g. Tungsten plugs, are formed within the PMD layer 151 to provide electric connection to the source region 132, the drain region 133, the p-type back gate region 160, and the gate conductor 142 (out of the plane of FIG. AH). Interconnects 153, electrically connected to the contacts 152, are formed over the PMD layer 151 using any suitable metallization scheme and provide electrical contact between the nanosheet transistor 101 and other components of the microelectronic device 100.

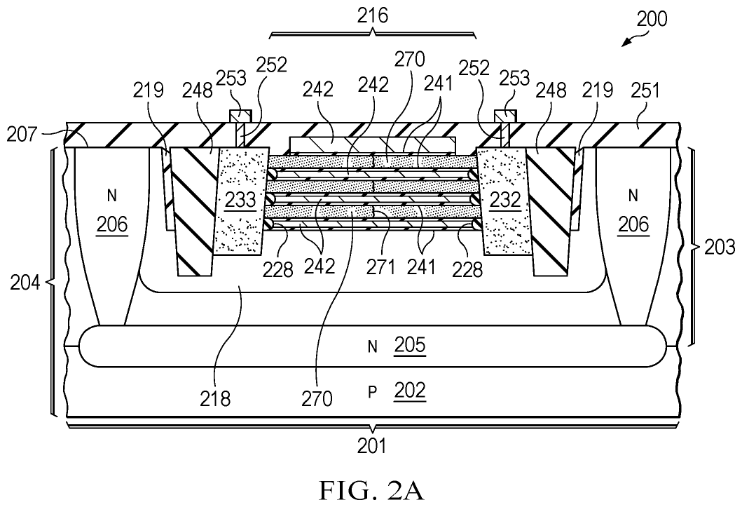

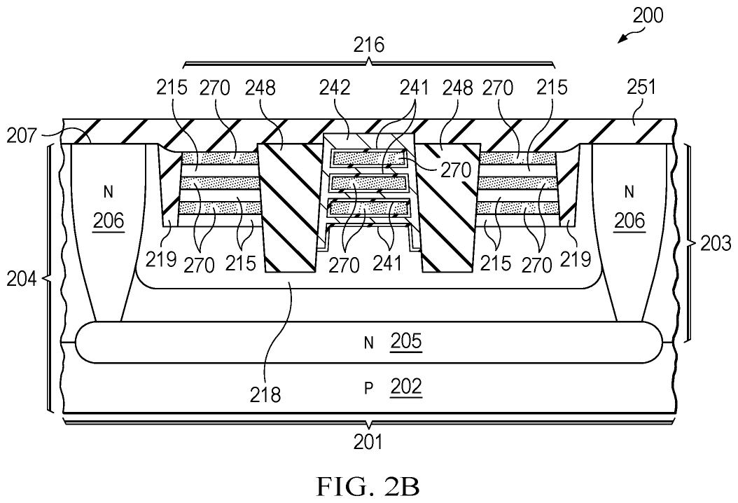

FIG. 2A and FIG. 2B, shows cross sections of a microelectronic device 200 containing a wide bandgap nanosheet n-type metal oxide semiconductor (NMOS) transistor 201 after formation. The wide bandgap nanosheet NMOS transistor may use silicon carbide as the crystalline nanosheet layer 270 and silicon dioxide as the sacrificial layer. Silicon may be used as the crystalline nanosheet layer 270 to form a nanosheet NMOS transistor with a smaller bandgap. The wide bandgap nanosheet NMOS transistor 201 is formed on a base wafer 202. On the base wafer 202, an epitaxial layer 203 is formed, the base wafer 202 and the epitaxial layer 203 forming a substrate 204 with a top surface 207. A PMD 251, contacts 252, and interconnects 253 are formed on the top surface 207. A deep well 206 surrounds the wide bandgap nanosheet NMOS transistor 201 and contacts a buried layer 205. A portion of a dielectric layer 219 remains after the formation of the nanosheet stack 216. A portion of the sacrificial layer 215 from the nanosheet stack 216 as deposited can be seen in FIG. 2B, but is not a functional portion of the wide bandgap nanosheet NMOS transistor 201. STI 248 surrounds the wide bandgap nanosheet NMOS transistor 201 providing isolation and removing possible parasitic pathways from the nanosheet stack 216 between the STI 248 and the dielectric layer 219. The wide bandgap nanosheet NMOS transistor 201 is formed in a p-type well region 218 using similar formation conditions to the p-type well region 118 referred to in FIG. 1AH. The wide bandgap nanosheet NMOS transistor 201 includes an n-type source region 232, a n-type drain region 233, crystalline nanosheet layers 270 with a crystalline nanosheet interface 271, a nanosheet gate dielectric layer 241, and a gate conductor 242. An inner spacer dielectric 228 and the nanosheet gate dielectric layer 241 electrically isolate the gate conductor 242 from the crystalline nanosheet layers 270. Additionally, a lightly doped drain (not specifically shown) may be formed using conditions similar to those used to form the n-type buffer region 126 referred to in FIG. 1AL Unless otherwise indicated, the components of the wide bandgap nanosheet NMOS transistor 201 may be formed using conditions including a laser anneal process 165 similar to those used to form the corresponding components of the nanosheet transistor 101 described in FIG. 1AA through FIG. 1BI.

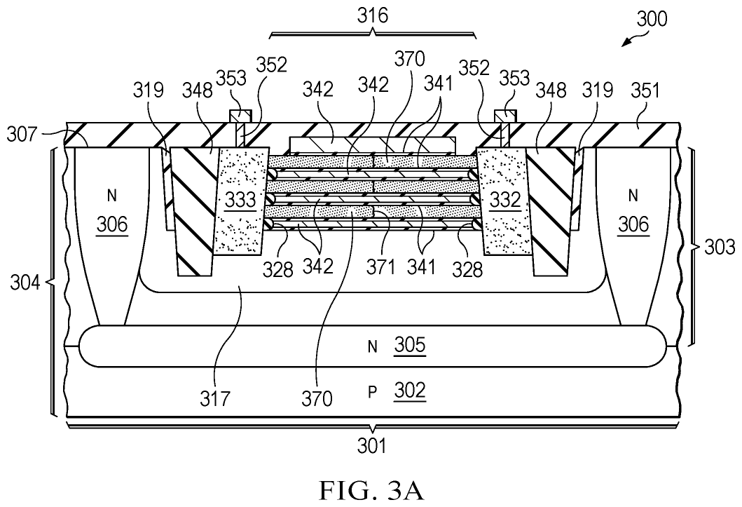

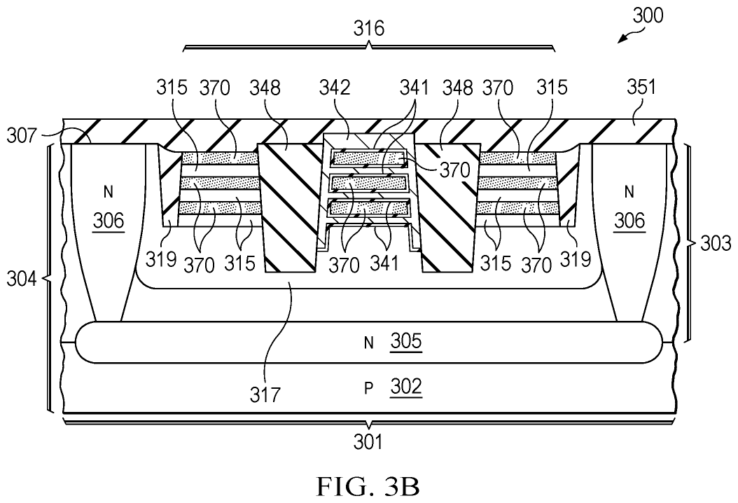

FIG. 3A and FIG. 3B, shows cross sections of a microelectronic device 300 containing a wide bandgap nanosheet p-type metal oxide semiconductor (PMOS) transistor 301 after formation. The wide bandgap nanosheet PMOS transistor may use silicon carbide as the crystalline nanosheet layer 370 and silicon dioxide as the sacrificial layer. Silicon may be used as the crystalline nanosheet layer 370 to form a nanosheet PMOS transistor with a smaller bandgap. The wide bandgap nanosheet PMOS transistor 301 is formed on a base wafer 302. On the base wafer 302, an epitaxial layer 303 is formed, the base wafer 302 and the epitaxial layer 303 forming a substrate 304 with a top surface 307. A PMD 351, contacts 352, and interconnects 353 are formed on the top surface 307. A deep well 306 surrounds the wide bandgap nanosheet PMOS transistor 301 and contacts a buried layer 305. A portion of the dielectric layer 319 remains after the formation of the wide bandgap nanosheet PMOS transistor 301. A portion of the sacrificial layer 315 from the nanosheet stack 316 as deposited can be seen in FIG. 3B, but is not a functional portion of the wide bandgap nanosheet PMOS transistor 301. STI 348 surrounds the wide bandgap nanosheet PMOS transistor 301 providing isolation and removing possible parasitic pathways from the nanosheet stack 316 between the STI 348 and the dielectric layer 319. The wide bandgap nanosheet PMOS transistor 301 is formed in an n-drift region 317 using similar formation conditions to the n-drift region 117 referred to in FIG. 1F. An optional n-type well region (not specifically shown) may also be formed in the n-drift region 317. The wide bandgap nanosheet PMOS transistor 301 includes a p-type source region 332, a p-type drain region 333, crystalline nanosheet layers 370 with a crystalline nanosheet interface 371, a nanosheet gate dielectric layer 341, and a gate conductor 342. An inner spacer dielectric 328 and the nanosheet gate dielectric layer 341 electrically isolate the gate conductor 342 from the crystalline nanosheet layers 370. Additionally, a lightly doped drain (not specifically shown) may be formed using conditions similar to those used to form the p-type body region 125 referred to in FIG. 1L. Unless otherwise indicated, the components of the wide bandgap nanosheet PMOS transistor 301 may be formed using conditions including a laser anneal process 165 similar to those used to form of the corresponding components of the nanosheet transistor 101 described in FIG. 1AA through FIG. 1BI.

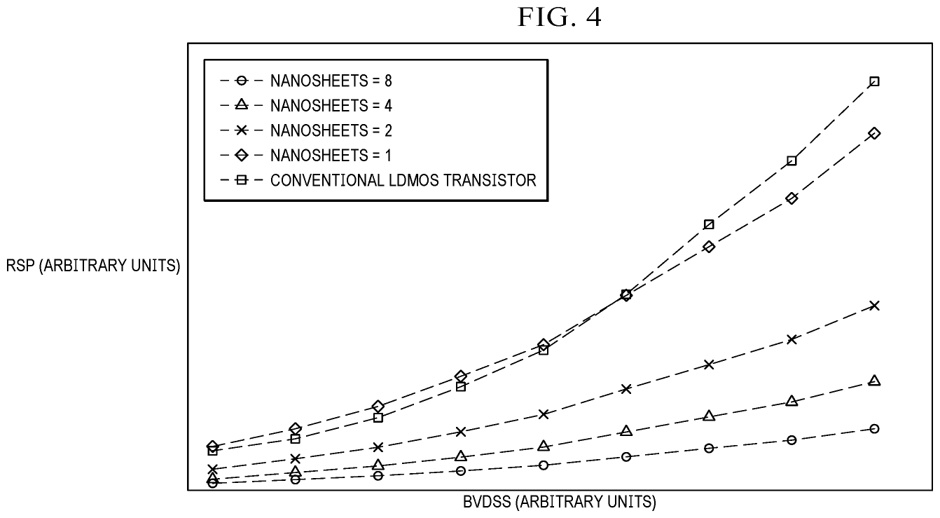

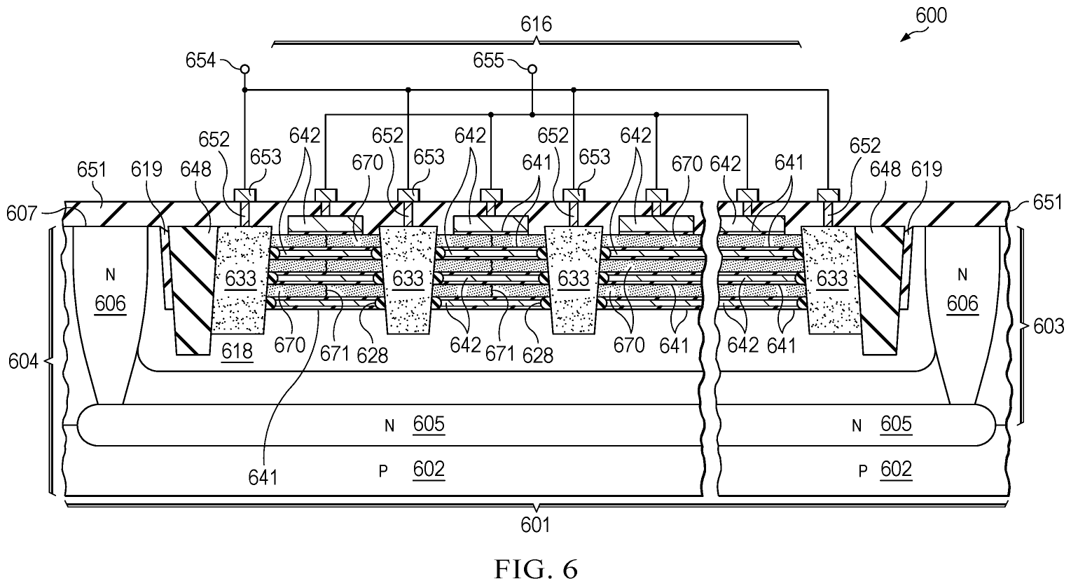

FIG. 4 is a graph of a simulation comparing the on-state resistance (Rsp) and the on-stage break down voltage (BVDSS) of nanosheet transistors 101 with varying numbers of crystalline nanosheet layers 170. The graph also includes the Rsp vs. BVDSS for a traditional LDMOS transistor. As shown in the graph of FIG. 6, the Rsp vs. BVDSS of a nanosheet transistor 101 with a single crystalline nanosheet layer 170 and a traditional LDMOS transistor are comparable. As the number of crystalline nanosheet layers 170 of the nanosheet transistor 101 increases from 2 to 4 to 8, a trend is shown, whereby an increased number of nanosheets in a given nanosheet transistor 101 results in a lower Rsp for a given BVDSS. The lower Rsp at a given BVDSS is advantageous for LDMOS nanosheet transistors 101 with respect to cost and performance as LDMOS geometries shrink.

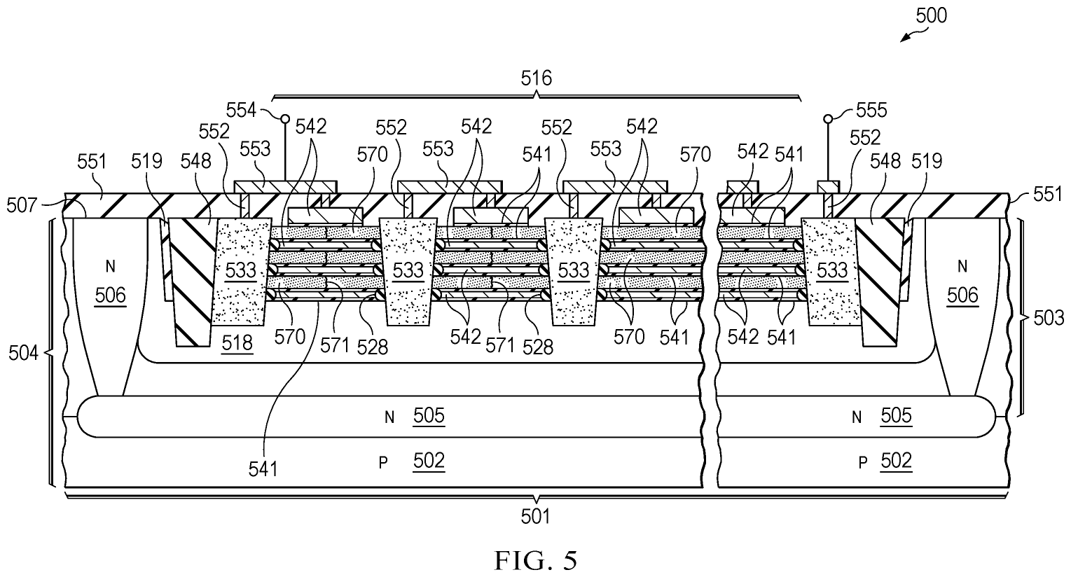

Referring to FIG. 5, a cross section of a nanosheet resistor 501 is shown. The nanosheet resistor 501 may provide a convenient resistor component for a microelectronic device 100 containing other nanosheet components such as the nanosheet transistor 101. The nanosheet resistor 501 is formed on a base wafer 502. Over the base wafer 502, an epitaxial layer 503 is formed, the base wafer 502 and the epitaxial layer 503 forming a substrate 504 with a top surface 507. A PMD 551, contacts 552, and interconnects 553 are formed over the top surface 507. A deep well 506 surrounds the nanosheet resistor 501 and contacts a buried layer 505. A portion of a dielectric layer 519 remains after the formation of the nanosheet stack 516. STI 548 surrounds the nanosheet resistor 501 providing isolation and removing parasitic pathways from the nanosheet stack 516 between the STI 548 and the dielectric layer 519. The nanosheet resistor 501 includes a nanosheet stack 516, crystalline nanosheet layers 570-1, 570-2, 570-3 . . . 570-X, collectively crystalline nanosheet layers 570, a crystalline nanosheet interface 571, a nanosheet gate dielectric layer 541, and a gate conductor 542 into which a plurality of doped regions 533-1, 533-2, 533-3 . . . 533-X, collectively n-type regions 533, have been formed. A n-drift region 518 at least partially surrounds the components of the nanosheet resistor 501. An inner spacer dielectric 528 and the nanosheet gate dielectric layer 541 electrically isolate the gate conductor 542 from the crystalline nanosheet layers 570. The nanosheet resistor 501 has a first terminal 554 and a second terminal 555. In the example nanosheet resistor 501 current enters through first terminal 554 into the doped region 533-1. Current then flows from the doped region 533-1 into the crystalline nanosheet layers 570-1 and flows into the n-type doped region 533-2. The current path is repeated through the plurality of doped regions 533 and crystalline nanosheet layers 570 until the current reaches the doped region 533-X, from which the current exits the nanosheet resistor 501 through the doped region 533-X through a contact 552 and an interconnect 553 to the second terminal 555.

The overall resistance of the nanosheet resistor 501 may be determined by the number of the plurality of doped regions 533, and the length of the nanosheet stack 516. The resistance of the nanosheet resistor 501 can also be modified by modifying the n-drift region 518 dose, or by adding n-type buffer regions (not specifically shown) around the plurality of doped regions 533, the n-type buffer regions being similar to the n-type buffer region 126 referred to in FIG. 1AL. The electrical connection between each of the plurality of doped regions 533 to the gate conductor 542 through contacts 532 and an interconnect 553 may reduce any field effects. The components of the nanosheet resistor 501 may be formed using conditions including a laser anneal process 165 (referred to in FIG. 1AW) similar to those used to form the corresponding components of the nanosheet transistor 101 described in FIG. 1AA through FIG. 1BI.

Referring to FIG. 6, a cross section of a nanosheet metal oxide capacitor (MOSCAP) 601 is shown. The nanosheet MOSCAP 601 may provide convenient capacitor component for a microelectronic device 100 containing other nanosheet components such as the nanosheet transistor 101. The nanosheet MOSCAP 601 is formed on a base wafer 602. Over the base wafer 602, an epitaxial layer 603 is formed, the base wafer 602 and the epitaxial layer 603 forming a substrate 604 with a top surface 607. A PMD 651, contacts 652, and interconnects 653 are formed over the top surface 607. A deep well 606 surrounds the nanosheet MOSCAP 601 and contacts a buried layer 605. A portion of a dielectric layer 619 remains after the formation of the nanosheet stack 616. STI 648, surrounds the nanosheet MOSCAP 601 providing isolation and removing parasitic resistance pathways from the nanosheet stack 616 between the STI 648 and the dielectric layer 619.

The nanosheet MOSCAP 601 includes a nanosheet stack 616, crystalline nanosheet layers 670-1, 670-2, 670-3 . . . 670-X, collectively crystalline nanosheet layers 670, a crystalline nanosheet interface 671 a nanosheet gate dielectric layer 641, and a gate conductor 642 into which a plurality of doped regions 633-1, 633-2, 633-3 . . . 633-X, collectively doped regions 633, have been formed. A n-drift region 618 at least partially surrounds the components of the nanosheet MOSCAP 601. An inner spacer dielectric 628 and the nanosheet gate dielectric layer 641 electrically isolate the gate conductor 642 from the crystalline nanosheet layers 670. The nanosheet MOSCAP 601 has a first terminal 654 and a second terminal 655. The example nanosheet MOSCAP 601 may also be made with the opposite conductivity types of those described by changing n-type regions of the nanosheet MOSCAP 601 to p-type regions.

In the example nanosheet MOSCAP 601 The first terminal 654 is electrically connected in parallel to each of the plurality of doped regions 633 through interconnects 653 and contacts 652. The second terminal 655 of the nanosheet MOSCAP 601 is connected to the gate conductor 642 through interconnects 653 and contacts 652. The plurality of doped regions 633 connected to the first terminal 654 and the gate conductor 642 connected to the second terminal 655 are electrically isolated from each other by the nanosheet gate dielectric layer 641 and the inner spacer dielectric 628, and form the components of the nanosheet MOSCAP 601. The components of the nanosheet MOSCAP 601 may be formed using formation conditions including a laser anneal process 165 (referred to in FIG. 1X) similar to those used to form the corresponding components of the nanosheet transistor 101 described in FIG. 1AA through FIG. 1BI.

While various examples of the present disclosure have been described above, it should be understood that they have been presented by way of example and not limitation. As such, although foregoing examples are described to use various resist layers (e.g., Photoresist or photomask layers) to perform various process steps (e.g., Implant steps or etch steps), the present disclosure is not limited thereto. For example, one or more hard masks (including one or more layers) may be patterned to define various regions for subsequent process steps to be applied (e.g., Regions for receiving dopant atoms, regions to block etchants). Moreover, the resist layers may include multi-level resists instead of a single-level resist in some examples. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and their equivalents.

What is claimed is:

1. A microelectronic device, comprising:
first and second doped semiconductor regions over a semiconductor substrate; and
a semiconductor nanosheet layer connected between the first and second semiconductor regions and having a bandgap greater than 1.5 eV.

2. The microelectronic device as recited in claim 1, further comprising:
a gate electrode spaced apart from the nanosheet layer; and
a gate dielectric layer between the nanosheet layer and the gate electrode.

3. The microelectronic device as recited in claim 2, wherein the semiconductor nanosheet layer is one of first and second semiconductor nanosheet layers connected between the first and second doped semiconductor regions, and the gate electrode and the gate dielectric layer are between the first and second semiconductor nanosheet layers.

4. The microelectronic device as recited in claim 2, wherein the first doped semiconductor region is a source region and the second doped semiconductor region is a drain region, the source and drain regions having a first conductivity type and a first average dopant concentration, and further comprising a drain drift region having the first conductivity type and a lower second dopant concentration in the semiconductor nanosheet layer and extending from the drain region toward the source region, and a channel region between the drain drift region and the source region.

5. The microelectronic device as recited in claim 4, further comprising a well region having an opposite second conductivity type within the semiconductor nanosheet layer and the substrate, and extending from the source region towards the drain region.

6. The microelectronic device as recited in claim 4, wherein the source region extends into a trench within the substrate and further comprising a body region having the second conductivity type along sides and a bottom of the trench.

7. The microelectronic device as recited in claim 4, wherein the drain region extends into a trench within the substrate and further comprising a buffer region having the first conductivity type along sides and a bottom of the trench.

8. The microelectronic device as recited in claim 2, further comprising a gate trench extending through the semiconductor nanosheet layer, the gate electrode extending from the gate trench.

9. The microelectronic device as recited in claim 4, further comprising an inner spacer of a dielectric material between the first and second semiconductor nanosheet layers and touching the source region, the inner spacer electrically isolating the gate electrode from the source region and the drain region.

10. The microelectronic device recited in claim 1, wherein the semiconductor nanosheet layer has a thickness greater than 10 nanometers.

11. The microelectronic device as recited in claim 1, wherein the semiconductor nanosheet layer comprises silicon carbide.

12. A method of forming a microelectronic device, comprising:
forming a trench in a semiconductor substrate having a first conductivity type;
forming a semiconductor nanosheet stack in the trench, including a semiconductor nanosheet layer and a sacrificial layer;
forming a source region and a drain region having an opposite second conductivity type extending into the semiconductor nanosheet stack;
removing the sacrificial layer between the source region and the drain region;
annealing the semiconductor nanosheet layer;
forming a gate dielectric layer on the semiconductor nanosheet layer; and
forming a gate conductor on the gate dielectric layer.

13. The method of claim 12, wherein forming the semiconductor nanosheet stack includes forming first and second semiconductor nanosheet layers, the sacrificial layer being between the first and second semiconductor nanosheet layers.

14. The method of claim 13, wherein forming the source region and the drain region includes forming a source trench and a drain trench extending into the semiconductor nanosheet stack, and further comprising forming recesses in the sacrificial layer at sidewalls of the source trench and the drain trench, and filling the recess with an inner spacer, the inner spacer electrically isolating the gate conductor from the source region and the drain region.

15. The method of claim 13, wherein forming the drain region includes forming a drain trench extending into the semiconductor nanosheet stack, and further comprising forming a buffer region of the second conductivity type along a sidewall of the drain trench.

16. The method of claim 13, further comprising forming a drift region of the second conductivity type in the semiconductor nanosheet stack and the semiconductor substrate, the drift region extending from the drain region toward the source region.

17. The method of claim 13, further comprising forming a body region of the first conductivity type in the semiconductor nanosheet stack, the body region extending from the source region toward the drain region.

18. The method of claim 13, further comprising forming a well region of the first conductivity type in the semiconductor nanosheet stack and the semiconductor substrate, the well region surrounding a body region and the source region.

19. The method of claim 13, further comprising forming first and second gate trenches extending through the semiconductor nanosheet stack, the gate conductor extending from the first gate trench to the second gate trench.

20. The method of claim 13, wherein the semiconductor nanosheet layer comprises silicon carbide.

21. The method of claim 13, wherein the semiconductor nanosheet layer comprises gallium oxide (Ga₂O₃).
